(19) United States
(12) Patent Application Publication
(10) Pub. No.: US 2006/0061963 A1
(43) Pub. Date: Mar. 23, 2006

(54) Wireless virtual docking

(76) Inventor: Sidney B. Schrum, Allen, TX (US)

Correspondence Address: CARSTENS & CAHOON, LLP, P O BOX 802334, DALLAS, TX, 75380, US

(21) Appl. No.: 11/231,630

(22) Filed: Sep. 21, 2005

Related U.S. Application Data
(60) Provisional application No. 60/611,658, filed on Sep. 21, 2004.

(51) Int. Cl. H05K 5/00

(52) U.S. Cl. 361/686

(57) ABSTRACT

The present invention provides a wireless computer docking system wherein a computer with a UWB wireless transceiver forms a wireless connect with UWB-enabled peripheral devices without the need for a physical docking station. The computer may a laptop, notebook, or tablet computer, or PDA-type device. A device driver for a UWB chipset in the computer can arbitrate data streams and data rates for multiple wireless peripheral devices and can maps the peripheral device to an operating system (OS) on the computer, wherein the OS has visibility of the peripheral device and can handle both control and data operations for the peripheral device. The computer maintains configuration information for each peripheral device and applies this information when a peripheral device is within UWB radio range.

### CROSS REFERENCE TO RELATED APPLICATION

This application is a non-provisional application and claims priority back to U.S. Provisional Application Ser. No. 60/611,658 filed on Sep. 21, 2004 entitled “Wireless Virtual Docking”, the technical disclosure of which are hereby incorporated herein by reference.

### TECHNICAL FIELD OF THE INVENTION

The present invention relates to a docking station to wirelessly connect a laptop computer to peripheral devices such as a monitor, keyboard or mouse. The wireless virtual docking eliminates the need for a physical docking station connected to the laptop.

### BACKGROUND OF THE INVENTION

Laptop computers offer mobility to many working professionals. A laptop is generally light weight but has the drawbacks of a reduced size monitor and keyboard. Once the user returns to his office, he may prefer to continue work with a larger monitor and a full size keyboard.

Laptop computers today utilize a physically-connected mechanical/electrical solution to attach a standard set of peripherals to the computing platform, including display (monitor), external keyboard, external mouse or pointing device, printer and other cabled devices. This is commonly known as a docking station or port replicator. A physical connection is made between the laptop and the docking station, at which time the docking station provides the necessary ports to connect to those peripherals. The primary purpose of the replicator is to provide a fast and convenient mechanism to allow the laptop computer to attach or detach from these peripheral devices without having to physically disconnect each of the respective cables from the computer.

While the replicator solutions available today provide a certain level of convenience in regards to fast connect/disconnect, they also raise concerns concerning cost and reliability.

FIG. 1 provides a block diagram of the prior art physical docking system 100. The system 100 includes a laptop 102 and the docking station 104. The docking station can also be referred to as a port replicator because it replicates many of the ports located on the back of the laptop. Laptop computers today utilize a physically-connected mechanical/electrical solution to attach a standard set of peripherals including a printer 110, a display 112 (monitor), external keyboard 114, external mouse 116, or other pointing device, and/or LAN connector 118. The primary purpose of the replicator is to provide a fast and convenient mechanism to allow the laptop computer to attach or detach from these peripheral devices without having to physically disconnect each of the respective cables from the computer. While the replicator solutions available today provide a certain level of convenience in regards to fast connect/disconnect, the problem with these devices concerns both cost and reliability. The invention proposes to address both of these primary concerns while also providing added convenience.

Present day replicator architectures typically extend the internal PCI bridge chipset from inside the laptop to an external box, which then connects to each of the peripherals using legacy and/or modern interfaces. These legacy connections are shown in FIG. 2A which illustrates the rear panel 202 of laptop computer 200 having a monitor 204. The connections can include popular connections such as USB ports 202, IEEE 1284 (Centronics) parallel 208, RS232 serial 212, PS/2-style mouse and keyboard connector 214, VGA and/or DVI-style display (monitor) connections 216, IEEE 1394 (Firewire), and even modem flash card ports such as Sony's Memorystick, Compact Flash, and others. The interface between the docking station and the laptop typically uses a specialized, high-pincount connector assembly 210 that includes an alignment feature and even hot-plug capability. Because of the complexity of this connector, the current replicator solution is fairly expensive.

To compound the problem list, the frequent dock/undock (insert/uninsert) operations can cause failure of the docking connector itself. FIG. 2B provides a view of a standard docking station 250. The station has a surface 258 that might include alignment grooves 256. A central hub 252 contains the mating connector 254 for the assembly 210 discussed above. In other words, the user must align the laptop with the replicator before physically engaging it. A misalignment can cause pin damage and ultimately failure of the replicator port. A rear view of the hub 252 is provided in FIG. 2C and it includes many if not more of the same ports located on the back of the laptop. These are used to connect to the printer 260, monitor 262, keyboard 264, or LAN 266.

Another current port replicator solution does not use a PCI-like connector, but rather utilizes a USB connection between the laptop and the peripherals. The key problem here is one of bandwidth, as the USB interface is not capable of supporting the combined data rates of the various peripherals, particularly the video for the display. So while this approach addresses some of the cost and reliability challenges, it does not address the performance needs for a complete docking solution and all attached peripherals.

Therefore, a need exists for a method of creating connectivity with the base station without the need for physically connecting the laptop to the docking station. Such a solution must provide the same results and offer the necessary bandwidth for today's increased data rates.

### SUMMARY OF THE INVENTION

With the rapid innovation in wireless technology and the FCC's opening of the ultra-wideband (UWB) spectrum for public use, greater bandwidth is now available. The present invention provides a wireless computer docking system wherein a computer with a UWB wireless transceiver forms a wireless connect with UWB-enabled peripheral devices without the need for a physical docking station. The computer may a laptop, notebook, or tablet computer, or PDA-type device.

A device driver for a UWB chipset in the computer can arbitrate data streams and data rates for multiple wireless peripheral devices and can maps the peripheral device to an operating system (OS) on the computer, wherein the OS has visibility of the peripheral device and can handle both control and data operations for the peripheral device. The computer maintains configuration information for each peripheral device and applies this information when a peripheral device is within UWB radio range.

### BRIEF DESCRIPTION OF THE DRAWINGS

The novel features believed characteristic of the invention are set forth in the appended claims. The invention itself, however, as well as a preferred mode of use, further objectives and advantages thereof, will best be understood by reference to the following detailed description of an illustrative embodiment when read in conjunction with the accompanying drawings, wherein:

FIG. 1 is a block diagram of current docking station/port replicator;

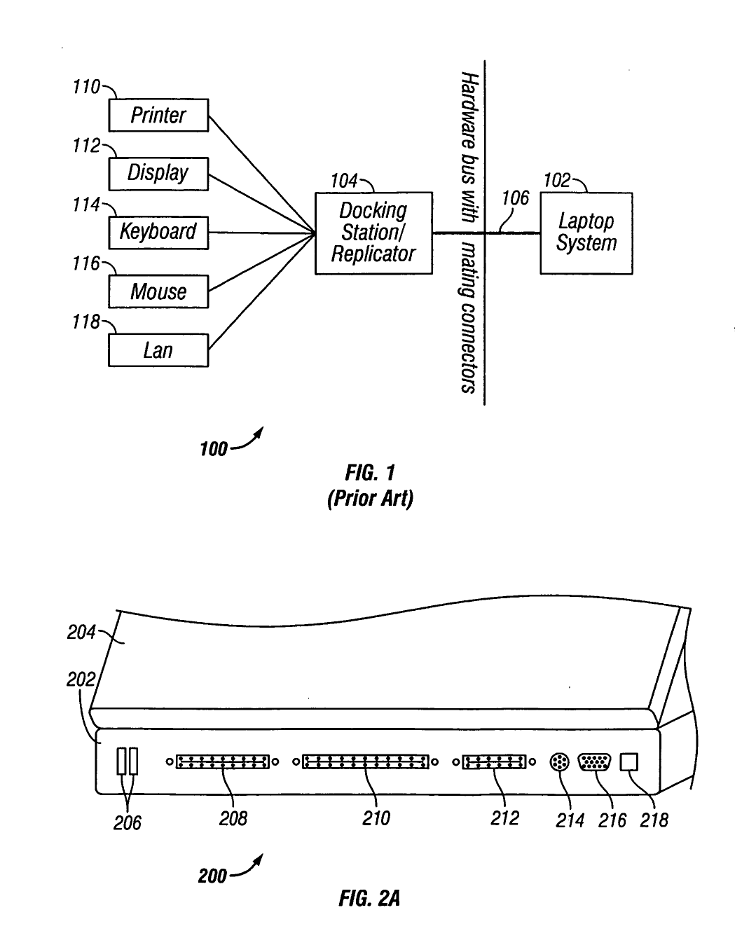

FIG. 2A illustrates the rear panel of a typical laptop, showing the real estate used for connection to a prior art docking station;

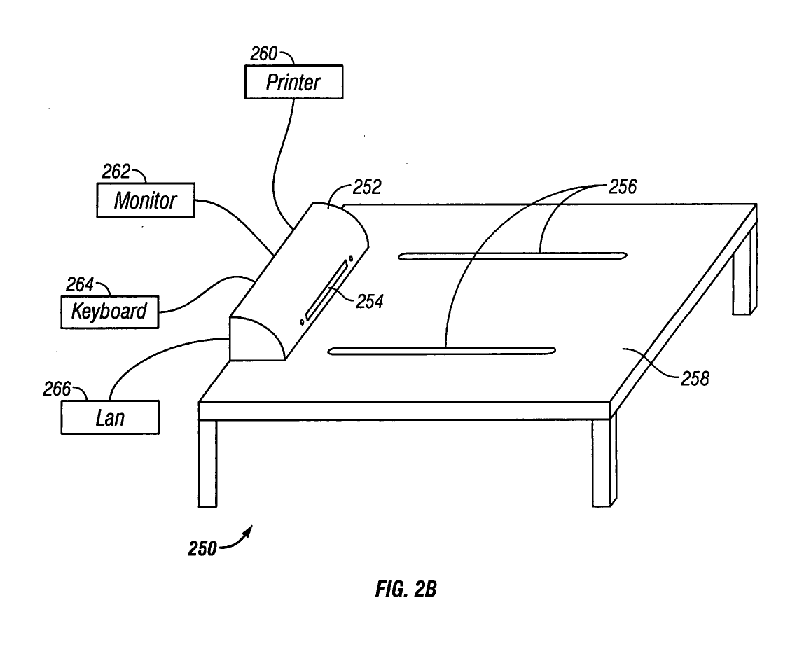

FIGS. 2B and 2C provide more detailed views of prior art docking stations.

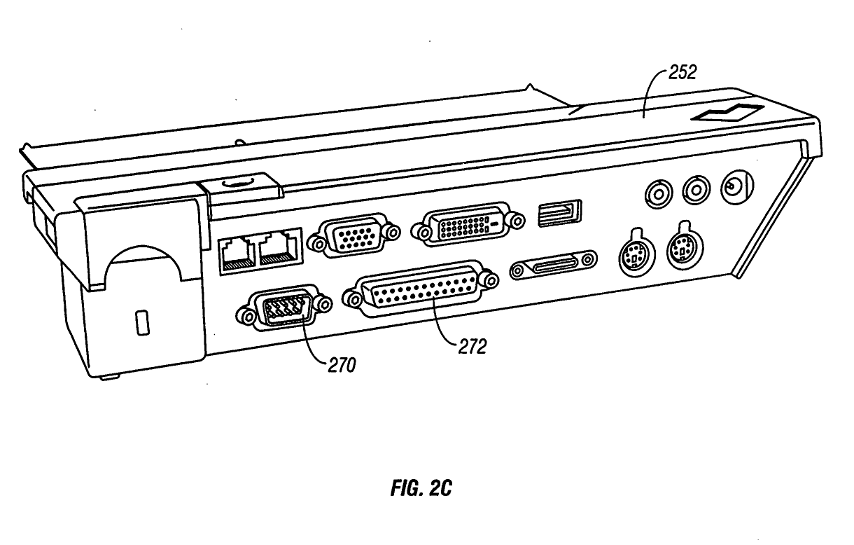

FIG. 3 is a block diagram illustrating an ultra-wideband virtual docking system in accordance with an embodiment of the present invention;

FIG. 4 is a block diagram of the laptop side of a wireless docking system; and

FIG. 5 is a block diagram of a UWB wireless peripheral device.

### DETAILED DESCRIPTION OF THE INVENTION

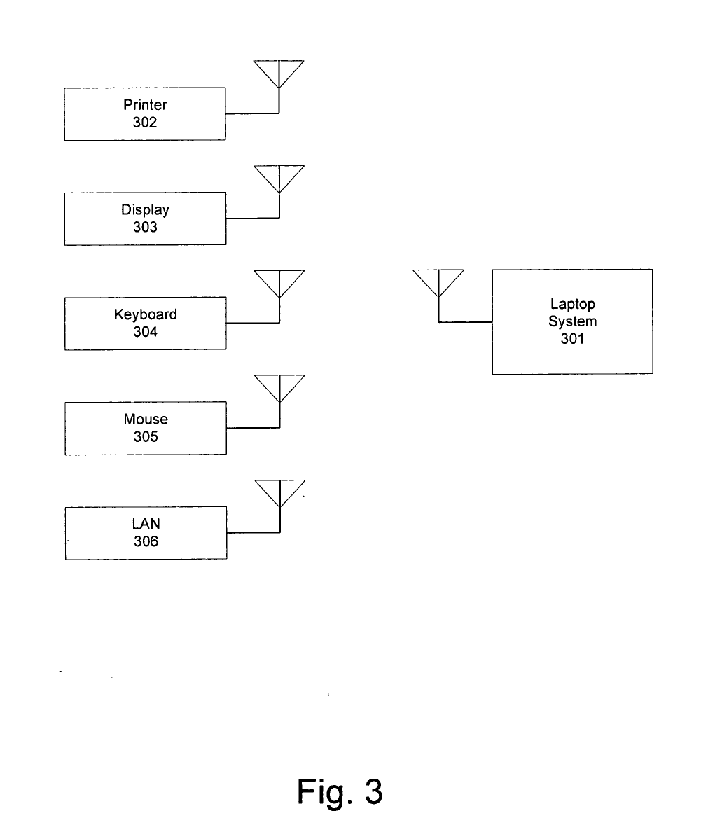

FIG. 3 is a block diagram illustrating an ultra-wideband virtual docking system in accordance with an embodiment of the present invention. With the opening of the ultra-wideband (UWB) spectrum by the FCC for public use, greater bandwidth is now available with the rapid innovation in wireless technology, allowing a laptop user to connect to peripherals without the need for cables.

Much recent interest has been directed towards the development of packet radio communication systems capable of providing data-intensive communication services. For instance, the IEEE 802.15.3a operating specification contemplates an Orthogonal Frequency Division Multiplexing (OFDM) UWB communication system, capable of communicating data over wide bandwidths and short ranges.

UWB is defined as any radio technology having a spectrum that occupies a bandwidth greater than 20 percent of the center frequency, or a bandwidth of at least 500 MHz. Modern UWB systems use modulation techniques such as OFDM to occupy these extremely wide bandwidths.

OFDM distributes data over a large number of carriers that are spaced at precise frequencies. This spacing provides the orthogonality in this technique, which prevents interference from adjacent tones. The benefits of OFDM include high-spectral efficiency, resiliency to radio frequency (RF) interference, and lower multipath distortion. OFDM used for UWB transmission results in a novel physical layer system for the enablement of high bit rate, short-range communication networks.

The seminal article on OFDM is “Data Transmission by Frequency-Division Multiplexing Using the Discrete Fourier Transform”, by S. B. Weinstein and Paul M. Ebert in IEEE Transactions on Communication Technology, Vol. com-19, No. 5, October 1971, the contents of which are hereby incorporated by reference.

The UWB spectrum from 3.1-10.6 GHz is divided into 14 bands of 528 MHz each, implying 14 carrier frequencies. These bands are further grouped into band groups, each having two or three adjacent frequency bands.

The present invention replaces the hardwired docking station/port replicator with multiple UWB wireless devices 302-306 that are each capable of establishing a direct wireless connection with the laptop system 301, as shown in FIG. 3. The wireless interface between the laptop 301 and the peripheral devices 302-306 no longer requires a docking station with a high pin count connector, which increases the reliability of the port replicator and decreases its cost.

Wireless peripheral devices may be added to the system individually, allowing the cost to increase incrementally according to the actual functionality required by the user. The wireless docking allows the laptop user to quickly associate the computer 301 with the UWB-docked peripheral devices 302-306 by merely placing the laptop in proximity with the peripherals rather than taking the time to ensure a precise mechanical connection is established (as required in prior art systems). The bandwidth and effective throughput of the UWB wireless connections can be superior to that of a USB solution, with data rates capable of exceeding 1 Gbps.

The present invention affords greater freedom in the physical placement of the UWB-wireless-docked devices due to the lack of a wired connection between the laptop and the replicator, and between the replicator and the peripheral devices. The UWB wireless peripheral devices 302-306 may be place anywhere within radio range of the UWB device in the laptop 301, providing greater convenience for the user.

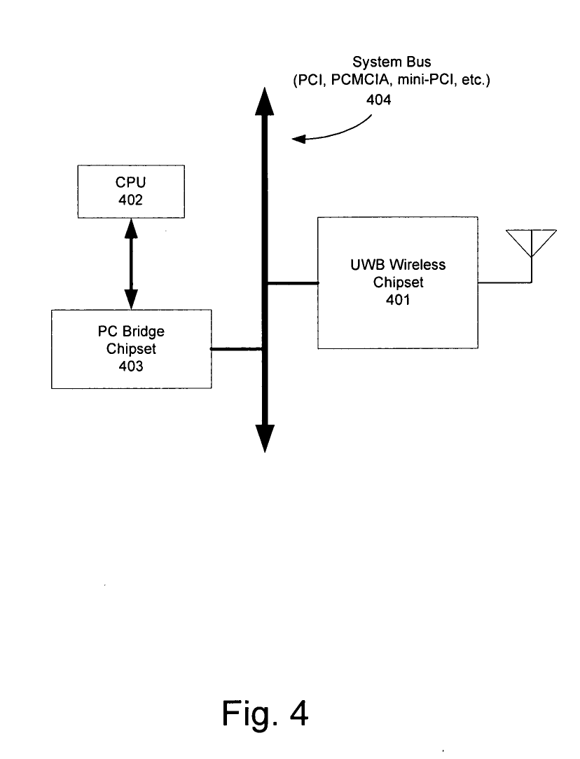

FIG. 4 is a block diagram of the laptop side of a wireless docking system. The design of the invention may be implemented in the following described manner, or in similar approaches which achieve the same basic connectivity. On the laptop, an UWB wireless chipset 401 is connected to the computer via an internal system bus 404, such as Peripheral Component Interconnect (PCI), Personal Computer Memory Card International Association (PCMCIA), or mini-PCI. This provides the host side of the wireless connection. The wireless chipset communications to the central processing unit (CPU) 402, memory, and/or other peripherals through a standard PC bridge chipset 408.

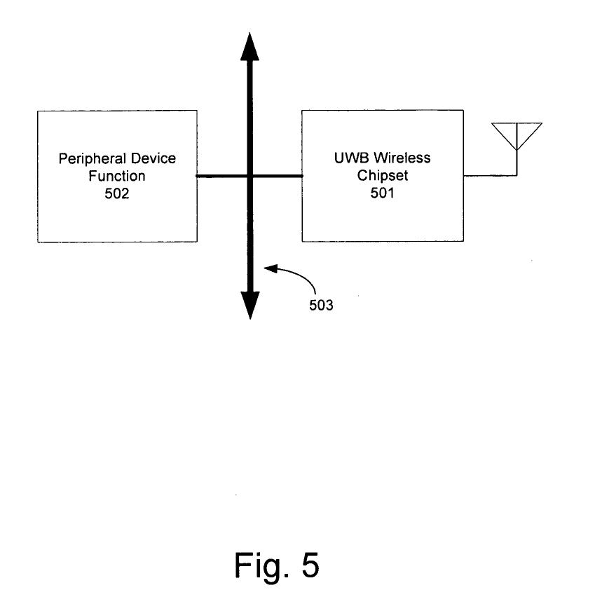

FIG. 5 is a block diagram of an UWB wireless peripheral device. The internal construction may vary with each UWB peripheral device. The example depicted in FIG. 5 is a simplified configuration that enables basic UWB wireless functionality. A UWB wireless chipset 501 provides connectivity between the peripheral device function 502 and the wireless medium. An internal wired bus 503 is used to attach the peripheral device function to the UWB wireless chipset.

The UWB wireless system provides a virtual bus that allows the wireless peripherals to function as though they were locally attached to the laptop system through a wired connection. The device driver for the laptop-side UWB chipset provides bridging functions between the laptop and UWB wireless medium, as well as arbitrating the various data streams and data rates of the wirelessly connected peripherals. Since UWB provides a time division (time slot) mechanism, bandwidth across the wireless channel for each of the different wirelessly docked peripherals can be scheduled according to their individual needs.

The laptop driver also provides a mapping function for each of the peripheral devices to the laptop operating system (OS) such that the OS has visibility for each device and can handle both control and data operations as though the wireless peripherals were physically attached to the laptop.

Central to virtual docking is the ability of a host (i.e. laptop) to discover and connect automatically to wireless peripherals that have previously been “introduced” (enrolled) to the host. This discovery and automatic connection requires specific procedures and records.

In a wired docking scenario, the first time the laptop is docked with a docking station the host laptop loads the device drivers for the peripherals. From then on, whenever a subsequent dock occurs the peripherals are automatically discovered and enumerated and the device drivers loaded.

Wireless virtual docking mirrors this wired docking scenario. When the user brings a host and “dockable” peripheral (that has been previously docked) into UWB range, it is equivalent to the wired scenario of plugging into the docking station. The differences are that with virtual docking the connection is wireless, coming within range is the indication that a peripheral should be docked, and “docking” can occur incrementally (as each device comes into range).

For each peripheral device that comes into radio range and/or is turned on, the host laptop establishes, records, and applies configuration information including enumeration values. The laptop handles device discovery, security enrollment, registration of wireless peripherals, and automatic loading and/or enablement of required software such as device drivers and user interface software. When the wireless peripheral device moves out of range or is turned off, the laptop “undocks” the peripheral device. The laptop can also permanently remove wireless peripheral devices from the virtual docking system including deleting the registration, software and configuration.

While the above description focuses on a laptop computer system, it should be understood that the features of the present invention can be applied to any computer system employing peripheral devices. This includes desk top computers as well as increasingly powerful handheld devices, which are likely to become the primary mobile computers of choice in the near future.

The description of the present invention has been presented for purposes of illustration and description, and is not intended to be exhaustive or limited to the invention in the form disclosed. Many modifications and variations will be apparent to those of ordinary skill in the art. The embodiment was chosen and described in order to best explain the principles of the invention, the practical application, and to enable others of ordinary skill in the art to understand the invention for various embodiments with various modifications as are suited to the particular use contemplated. It will be understood by one of ordinary skill in the art that numerous variations will be possible to the disclosed embodiments without going outside the scope of the invention as disclosed in the claims.

I claim:

1. A wireless computer docking system comprising:
(a) a computer having a first wireless transceiver; and
(b) at least one peripheral device having a second wireless transceiver;
wherein the computer is able to dock with the peripheral device by establishing a wireless connection, wherein when the computer and peripheral device come within a specified radio range of each other the computer automatically discovers the presence of the peripheral device and loads driver software associated with the peripheral device.

2. The docking system according to claim 1, wherein the first and second wireless transceivers are ultra-wideband transceivers.

3. The docking system according to claim 1, wherein the computer is a laptop, notebook, or tablet computer, or PDA-type device.

4. The docking system according to claim 1, wherein the computer further comprises an ultra-wideband (UWB) wireless chipset coupled to a PC bridge or I/O chipset by a system bus.

5. The docking system according to claim 4, wherein a device driver for the UWB chipset can arbitrate data streams and data rates for multiple wireless peripheral devices.

6. The docking system according to claim 4, wherein a device driver for the UWB chipset maps the peripheral device to an operating system (OS) on the computer, wherein the OS has visibility of the peripheral device and can handle both control and data operations for the peripheral device.

7. The docking system according to claim 1, wherein the peripheral device further comprises an ultra-wideband wireless chipset coupled to peripheral device function by a system bus.

8. The docking system according to claim 1, wherein the computer maintains configuration information for the peripheral device and applies said configuration information when the peripheral device is within said radio range of the computer.

9. The docking system according to claim 1, further comprising multiple peripheral devices having wireless transceivers, wherein each peripheral device automatically docks with the computer individually as the peripheral device and computer come within the specified radio range of each other.

10. A method of associating peripheral devices to a computer, the method comprising the steps of:
(a) placing at least one peripheral device within a specified radio range of the computer, wherein the computer has a first wireless transceiver and the peripheral device has a second wireless transceiver; and
(b) establishing a wireless connection between the peripheral device and the computer, wherein when the computer and peripheral device come within the specified radio range of each other the computer automatically discovers the presence of the peripheral device and loads driver software associated with the peripheral device.

11. The method according to claim 10, wherein the wireless connection is an ultra-wideband connection.

12. The method according to claim 10, wherein the computer is a laptop, notebook, or tablet computer, or PDA-type device.

13. The method according to claim 10, further comprising associating multiple peripheral devices with the computer, wherein each peripheral device automatically establishes a wireless connection with the computer individually as the peripheral device and computer come within the specified radio range of each other.
